(19) United States
(12) Patent Application Publication
(10) Pub. No.: US 2022/0168918 A1
(43) Pub. Date: Jun. 2, 2022

(54) PROCESSING APPARATUS

(71) Applicant: DISCO CORPORATION, Tokyo (JP)

(72) Inventor: Takafumi OMORI, Tokyo (JP)

(21) Appl. No.: 17/454,840

(22) Filed: Nov. 15, 2021

(30) Foreign Application Priority Data
Dec. 2, 2020 (JP) 2020-200622

(51) Int. Cl. B26D 5/00; B26D 1/18; G06T 7/00

(52) U.S. Cl. CPC B26D 5/007; G06T 2207/30148; G06T 7/0004; B26D 1/185

(57) ABSTRACT

A control unit of a processing apparatus includes an abnormality detecting section configured to detect an abnormality in the processing apparatus, a processing stopping section configured to stop cutting processing by a cutting unit when an abnormality is detected, and a data collecting section configured to collect data related to the processing apparatus, during a standby time period between stopping of the processing and performing of an operation of recovery from the abnormality by an operator.

### BACKGROUND OF THE INVENTION

### Field of the Invention

The present invention relates to a processing apparatus that processes a workpiece.

### Description of the Related Art

Various processing apparatuses such as cutting apparatuses have conventionally been used to divide a wafer such as a semiconductor wafer into individual device chips (see Japanese Patent Laid-Open No. 2008-4807, for example).

### SUMMARY OF THE INVENTION

A processing apparatus described in Japanese Patent Laid-Open No. 2008-4807 has a specification for notifying an operator of an error that requires work by an operator, by sounding an alarm when the error has occurred. However, on a production site, the operator may manage a plurality of processing apparatuses, and may not be able to immediately perform an operation for recovery from the error to resume processing operation. Then, the processing apparatus only waits in a state in which processing is stopped. There is thus room for contrivance for utilizing a standby time period.

It is accordingly an object of the present invention to provide a processing apparatus that can effectively utilize a time period during which the processing apparatus is stopped.

In accordance with an aspect of the present invention, there is provided a processing apparatus including a holding table having a holding surface configured to hold a workpiece, a processing unit configured to process the workpiece held on the holding table, a processing feed unit configured to move the holding table relative to the processing unit, an imaging unit configured to image the workpiece held on the holding table, and a control unit, the control unit including an abnormality detecting section configured to detect an abnormality in the processing apparatus, a processing stopping section configured to stop processing by the processing unit when an abnormality is detected, and a data collecting section configured to collect data related to the processing apparatus, during a standby time period between stopping of the processing and performing of an operation of recovery from the abnormality by an operator.

Preferably, the control unit further includes a data analyzing section configured to analyze the data collected by the data collecting section. Preferably, the abnormality detecting section checks quality of a processed groove from an image of the processed groove imaged by the imaging unit.

Preferably, the processing apparatus further includes a plurality of transporting units configured to transport the workpiece in the processing apparatus, and the abnormality detecting section detects an abnormality in transportation by the transporting units. Preferably, the data collecting section images processed grooves in a plurality of regions by driving the imaging unit, and collects images of a plurality of the processed grooves as the data.

Preferably, the processing unit includes a cutting blade fixed to a distal end of a spindle and configured to form a processed groove in the workpiece and a motor configured to rotate the spindle, the processing apparatus further includes a diameter detecting unit configured to detect a diameter of the cutting blade, and the data collecting section detects the diameter of the cutting blade by the diameter detecting unit.

The present invention produces an effect of being able to effectively utilize a time period during which the processing apparatus is stopped.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view depicting an example of a configuration of a processing apparatus according to an embodiment;

FIG. 2 is a side view schematically depicting, partly in section, configurations of a cutting unit and a holding table of the processing apparatus illustrated in FIG. 1;

FIG. 3 is a perspective view of principal parts of the cutting unit illustrated in FIG. 2;

FIG. 4 is a front view schematically depicting a configuration of a diameter detecting unit of the processing apparatus illustrated in FIG. 1;

FIG. 5 is a plan view schematically depicting a workpiece that is under cutting processing by the processing apparatus illustrated in FIG. 1;

FIG. 6 is a diagram depicting an example of an image obtained by imaging a part of the workpiece at a time of performing a kerf check during the cutting processing by the processing apparatus illustrated in FIG. 1;

FIG. 7 is a plan view depicting an example of a wafer position at which image data as data collected by a data collecting section of the processing apparatus illustrated in FIG. 1 is obtained;

FIG. 8 is a plan view depicting another example of the wafer position at which the image data as data collected by the data collecting section of the processing apparatus illustrated in FIG. 1 is obtained;

FIG. 9 is a diagram depicting an example of a display screen displayed on a display unit when an abnormality detecting section of a control unit of the processing apparatus illustrated in FIG. 1 detects a chipping size error;

FIG. 10 is a diagram depicting an example of the display screen that is displayed when a recovery region or a data display region of the display screen illustrated in FIG. 9 is operated during obtainment of the image data by the data collecting section;

FIG. 11 is a diagram depicting an example of the display screen that is displayed when the data display region of the display screen illustrated in FIG. 9 is operated after the obtainment of the image data by the data collecting section; and

FIG. 12 is a perspective view depicting an example of a configuration of a processing apparatus according to a modification of the embodiment.

### DETAILED DESCRIPTION OF THE PREFERRED EMBODIMENT

An embodiment of the present invention will hereinafter be described in detail with reference to the drawings. The present invention is not limited by contents described in the following embodiment. In addition, constituent elements described in the following include constituent elements readily conceivable by those skilled in the art and essentially identical constituent elements. Further, configurations described in the following can be combined with each other as appropriate. In addition, various omissions, replacements, or modifications of configurations can be performed without departing from the spirit of the present invention.

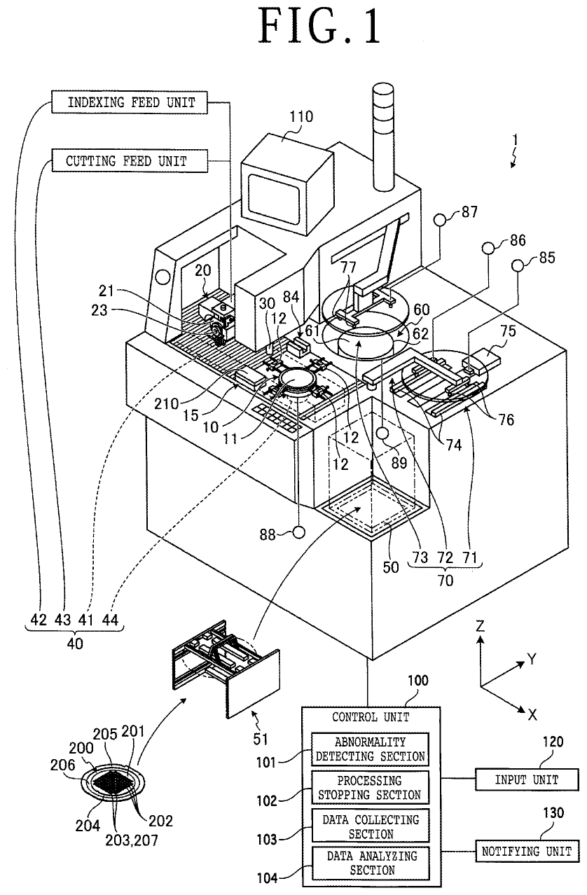

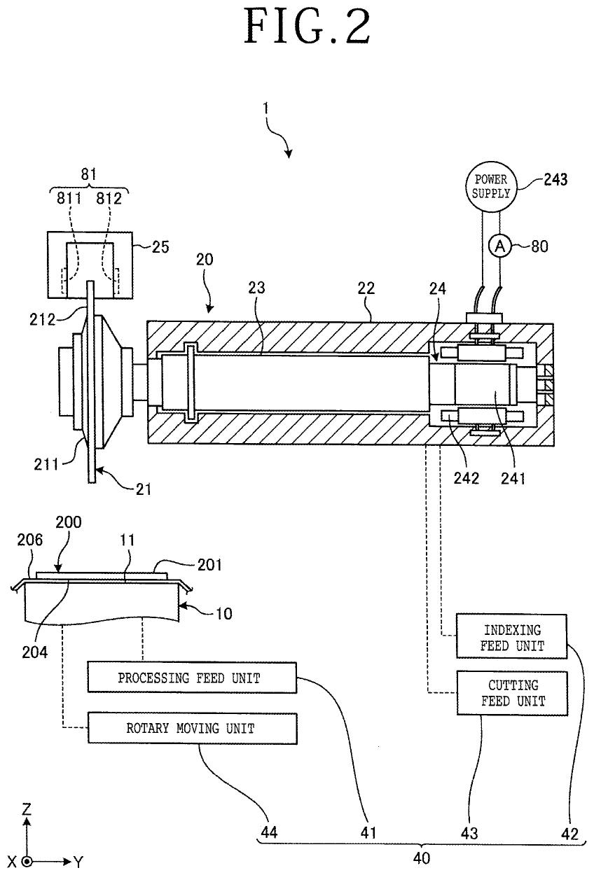

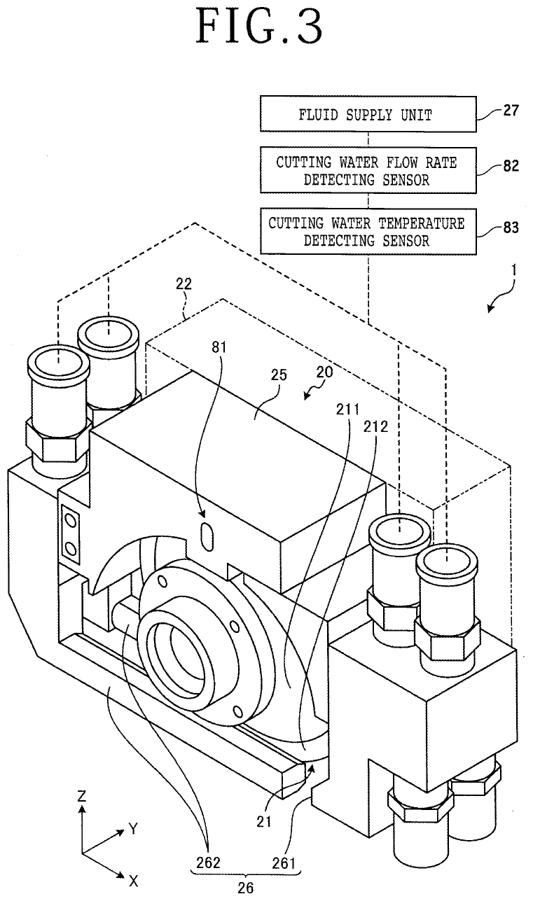

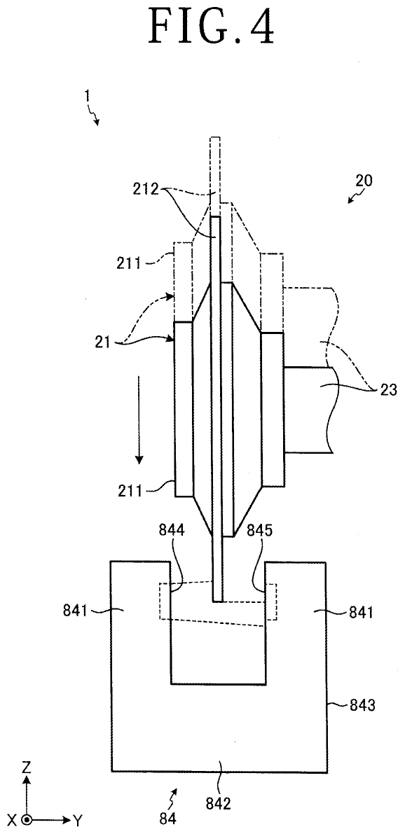

A processing apparatus according to the embodiment of the present invention will be described with reference to the drawings. FIG. 1 is a perspective view depicting an example of a configuration of the processing apparatus according to the embodiment. FIG. 2 is a side view schematically depicting, partly in section, configurations of a cutting unit and a holding table of the processing apparatus illustrated in FIG. 1. FIG. 3 is a perspective view of principal parts of the cutting unit illustrated in FIG. 2. FIG. 4 is a front view schematically depicting a configuration of a diameter detecting unit of the processing apparatus illustrated in FIG. 1.

A processing apparatus 1 illustrated in FIG. 1 according to the embodiment is a cutting apparatus that performs cutting processing (corresponding to processing) on a workpiece 200. The workpiece 200 to be processed by the processing apparatus 1 illustrated in FIG. 1 is a semiconductor wafer or an optical device wafer in a disk shape which includes silicon, gallium arsenide, silicon carbide (SiC), sapphire, or the like as a substrate. The workpiece 200 has a plurality of planned dividing lines 202 formed in a lattice manner on a top surface 201. A device 203 is formed in each region demarcated by the plurality of planned dividing lines 202. The device 203 is an integrated circuit such as an integrated circuit (IC) or a large scale integration (LSI) circuit or an image sensor such as a charge coupled device (CCD) image sensor or a complementary metal oxide semiconductor (CMOS) image sensor.

In addition, in the present invention, the workpiece 200 may be what is generally called a TAIKO (registered trademark) wafer whose central portion is thinned and which has a thick part formed as an outer circumferential portion of the wafer. In addition, in the present invention, the workpiece 200 is not limited to a wafer, and may be various kinds of workpieces in a plate shape such as a rectangular resin package substrate having a plurality of devices sealed by resin, a ceramic substrate, and a glass substrate.

In the embodiment, the workpiece 200 is supported by an annular frame 205 in a state in which an undersurface 204 on the underside of the top surface 201 is affixed to an adhesive tape 206 having the annular frame 205 fitted to an outer circumferential edge of the adhesive tape 206. The workpiece 200 according to the embodiment is divided into individual chips 207 along the planned dividing lines 202. Incidentally, the chips 207 each include a part of the substrate and a device 203 formed on the substrate.

### (Processing Apparatus)

The processing apparatus 1 is a cutting apparatus that holds the workpiece 200 by a holding table 10 and cuts the workpiece 200 along the planned dividing lines 202 by a cutting blade 21, to thereby divide the workpiece 200 into individual chips 207. The processing apparatus 1 includes the holding table 10 having a holding surface 11 that holds under suction the workpiece 200; a sub-chuck table 15; a cutting unit 20 that divides the workpiece 200 held on the holding table 10 along the planned dividing lines 202 by the cutting blade 21, and thereby forms a plurality of chips 207; and an imaging unit 30 that images the workpiece 200 held on the holding table 10. Incidentally, the sub-chuck table 15 is not essential.

In addition, as illustrated in FIG. 2, the processing apparatus 1 includes a moving unit 40 that moves the holding table 10 and a spindle 23 of the cutting unit 20 relative to each other. The moving unit 40 includes at least a processing feed unit 41 that processing-feeds the holding table 10 in an X-axis direction parallel with a horizontal direction; an indexing feed unit 42 that indexing-feeds the cutting unit 20 in a Y-axis direction parallel with the horizontal direction but orthogonal to the X-axis direction; a cutting feed unit 43 that cutting-feeds the cutting unit 20 in a Z-axis direction parallel with a vertical direction orthogonal to both the X-axis direction and the Y-axis direction; and a rotary moving unit 44 that rotates the holding table 10 about an axis parallel with the Z-axis direction.

The processing feed unit 41 moves the holding table 10 and the rotary moving unit 44 in the X-axis direction as a processing feed direction. The processing feed unit 41 thereby moves the holding table 10 relative to the cutting unit 20 along the X-axis direction. The indexing feed unit 42 moves the cutting unit 20 in the Y-axis direction as an indexing feed direction. The indexing feed unit 42 thereby moves the cutting unit 20 and the holding table 10 relative to each other along the Y-axis direction. The cutting feed unit 43 moves the cutting unit 20 in the Z-axis direction as a cutting feed direction. The cutting feed unit 43 thereby moves the cutting unit 20 and the holding table 10 relative to each other along the Z-axis direction. The rotary moving unit 44 is supported by the processing feed unit 41, supports the holding table 10, and is disposed in such a manner as to be movable in the X-axis direction together with the holding table 10.

The processing feed unit 41, the indexing feed unit 42, and the cutting feed unit 43 include a well-known ball screw provided rotatably about an axis, a well-known motor that rotates the ball screw about the axis, and well-known guide rails that support the holding table 10 or the cutting unit 20 movably in the X-axis direction, the Y-axis direction, or the Z-axis direction.

The holding table 10 has a disk shape. The holding surface 11 that holds the workpiece 200 is formed of porous ceramic or the like. In addition, the holding table 10 is provided in such a manner as to be movable in the X-axis direction by being provided in a manner of being movable by the processing feed unit 41 between a processing region below the cutting unit 20 and a loading and unloading region that is separated from a lower part of the cutting unit 20 and in which the workpiece 200 is loaded and unloaded. The holding table 10 is provided in such a manner as to be rotatable by the rotary moving unit 44 about an axis parallel with the Z-axis direction. The holding table 10 is connected to a vacuum suction source not illustrated. The holding table 10 sucks and holds the workpiece 200 mounted on the holding surface 11, by being sucked from the vacuum suction source. In the embodiment, the holding table 10 sucks and holds the undersurface 204 side of the workpiece 200 via the adhesive tape 206. In addition, as illustrated in FIG. 1, a plurality of clamp units 12 that clamp the annular frame 205 are provided around the periphery of the holding table 10.

The cutting unit 20 is a processing unit that has the cutting blade 21 fitted to the spindle 23 and thereby cuts the workpiece 200 held on the holding table 10. The cutting unit 20 is provided in such a manner as to be movable in the Y-axis direction by the indexing feed unit 42 with respect to the workpiece 200 held on the holding table 10, and is provided in such a manner as to be movable in the Z-axis direction by the cutting feed unit 43 with respect to the workpiece 200 held on the holding table 10. The cutting unit 20 allows the indexing feed unit 42 and the cutting feed unit 43 to position the cutting blade 21 at any position of the holding surface 11 of the holding table 10.

As illustrated in FIG. 2, the cutting unit 20 includes the cutting blade 21; a spindle housing 22 provided in such a manner as to be movable in the Y-axis direction and the Z-axis direction by the indexing feed unit 42 and the cutting feed unit 43; the spindle 23 that is provided to the spindle housing 22 in such a manner as to be rotatable about an axis and that has an end thereof fitted with the cutting blade 21; a spindle motor 24 as a motor that rotates the spindle 23 about the axis; a blade cover 25 illustrated in FIG. 3, the blade cover 25 being fitted to an end surface of the spindle housing 22; and a nozzle 26 illustrated in FIG. 3, the nozzle 26 supplying cutting water as fluid to the cutting blade 21.

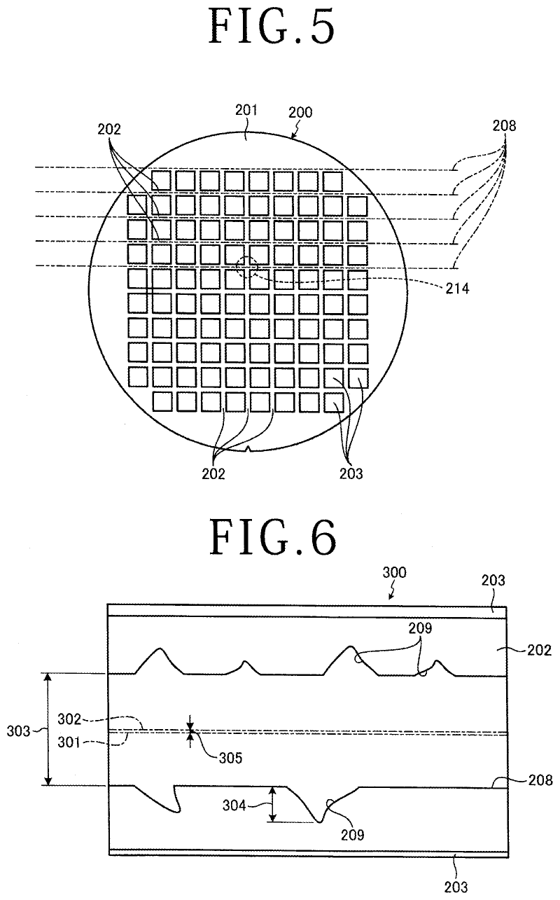

The cutting blade 21 is a very thin cutting grindstone having substantially a ring shape. The cutting blade 21 is fixed to a distal end of the spindle 23. The cutting blade 21 forms processed grooves 208 (indicated by chain double-dashed lines in FIG. 5) in the workpiece 200. In the embodiment, as illustrated in FIG. 2, the cutting blade 21 is what is generally called a hub blade including a circular base 211 in the form of a circular ring and a cutting edge 212 in the form of a circular ring which is disposed on an outer circumferential edge of the circular base 211 and cuts the workpiece 200. The cutting edge 212 is formed of abrasive grains such as diamond or cubic boron nitride (CBN) and a bonding material (binding material) such as metal or resin, and is formed with a predetermined thickness. The cutting edge 212 of the cutting blade 21 is worn by cutting of the workpiece 200. Incidentally, in the present invention, the cutting blade 21 may be what is generally called a washer blade including only the cutting edge 212.

The spindle 23 has the cutting blade 21 fixed to a distal end thereof, and is rotated about the axis by the spindle motor 24. The spindle 23 thereby rotates the cutting blade 21. The spindle motor 24 includes a rotor 241 that is provided to the spindle 23 and rotates integrally with the spindle 23; and a stator 242 that is provided on the peripheral side of the rotor 241 and to the spindle housing 22 and rotates the rotor 241 by being supplied with power from a power supply 243. The stator 242 rotates the rotor 241, and thereby the spindle motor 24 rotates the spindle 23 about the axis.

The blade cover 25 covers at least an upper part of the cutting blade 21. The blade cover 25 is fixed to an end surface of the spindle housing 22. As illustrated in FIG. 3, the nozzle 26 includes a shower nozzle 261 and a pair of blade nozzles 262. The nozzles 261 and 262 are supplied with cutting water from a fluid supply unit 27. The shower nozzle 261 faces a point of the cutting edge 212 of the cutting blade 21 in the X-axis direction, and supplies the cutting water to the point of the cutting edge 212 of the cutting blade 21 during cutting. The blade nozzles 262 extend in parallel with the X-axis direction, and are arranged at a distance from each other in the Y-axis direction. A lower end of the cutting edge 212 of the cutting blade 21 is positioned between the blade nozzles 262. The blade nozzles 262 supply the cutting water to the lower end of the cutting edge 212 of the cutting blade 21 during cutting. The shower nozzle 261 and the blade nozzles 262 of the nozzle 26 supply the cutting water, and thereby the nozzle 26 supplies, via the cutting blade 2, the cutting water to a processing point at which the cutting blade 21 cuts the workpiece 200.

Incidentally, the axis of the cutting blade 21 and the spindle 23 of the cutting unit 20 is set parallel with the Y-axis direction.

The sub-chuck table 15 is provided at a position adjacent to the holding table 10 in such a manner as to be movable, together with the holding table 10, in the X-axis direction by the processing feed unit 41. The sub-chuck table 15 holds under suction a dressing board 210 on a holding surface. The dressing board 210 is cut by the cutting edge 212 of the cutting blade 21. The dressing board 210 thereby sets the cutting edge 212 of the cutting blade 21 whose cutting capability is degraded due to loading or dulling, and removes cutting waste adhering to the cutting edge 212 of the cutting blade 21. The dressing board 210 consequently restores the cutting capability of the cutting edge 212 of the cutting blade 21. Restoring the cutting capability of the cutting edge 212 of the cutting blade 21 by cutting the dressing board 210 by the cutting edge 212 of the cutting blade 21 and thereby setting the cutting edge 212 of the cutting blade 21 is referred to as dressing (referred to also as dress). Incidentally, the dressing board 210 is obtained by fixing abrasive grains by a bonding material (binding material), and in the embodiment, the planar shape of the dressing board 210 is formed in the shape of a rectangular flat plate. Incidentally, in a case where the sub-chuck table 15 is not provided, the dressing board 210 is held on the holding table 10 to set the cutting edge 212 of the cutting blade 21.

The imaging unit 30 is disposed above the holding table 10 that moves between the loading and unloading region and the processing region. The imaging unit 30 includes an imaging element that images a region to be divided in the workpiece 200 that has not yet been cut and that is held on the holding table 10. The imaging element is, for example, a CCD imaging element or a CMOS imaging element. The imaging unit 30 obtains an image by imaging the workpiece 200 held on the holding table 10, and outputs the obtained image to a control unit 100.

In addition, the processing apparatus 1 includes an unillustrated X-axis direction position detecting unit for detecting the position in the X-axis direction of the holding table 10, an unillustrated Y-axis direction position detecting unit for detecting the position in the Y-axis direction of the cutting unit 20, and a Z-axis direction position detecting unit for detecting the position in the Z-axis direction of the cutting unit 20. The X-axis direction position detecting unit and the Y-axis direction position detecting unit can include a linear scale parallel with the X-axis direction or the Y-axis direction and a read head. The Z-axis direction position detecting unit detects the position in the Z-axis direction of the cutting unit 20 by motor pulses. The X-axis direction position detecting unit, the Y-axis direction position detecting unit, and the Z-axis direction position detecting unit output the position in the X-axis direction of the holding table 10 or the position in the Y-axis direction or the Z-axis direction of the axis of the spindle 23 and the cutting blade 21 of the cutting unit 20 to the control unit 100.

Incidentally, in the embodiment, the position in the X-axis direction and the position in the Y-axis direction and the Z-axis direction of the holding table 10 and the cutting unit 20 of the processing apparatus 1 are determined on the basis of a predetermined reference position not illustrated. In the embodiment, the position in the X-axis direction and the position in the Y-axis direction and the Z-axis direction are determined by distances in the X-axis direction, the Y-axis direction, and the Z-axis direction from the reference position. In addition, in the embodiment, the reference position in the Z-axis direction is located on the same plane as the holding surface 11.

In addition, the processing apparatus 1 includes a cassette elevator 50 that is mounted with a cassette 51 housing a plurality of workpieces 200 that have undergone or not cutting processing and moves the cassette 51 in the Z-axis direction; a cleaning unit 60 that cleans a workpiece 200 that has undergone the cutting processing; and a transporting unit 70 that loads and unloads the workpiece 200 into and from the cassette 51 and transports the workpiece 200 between the cassette 51, the holding table 10, and the cleaning unit 60.

The cleaning unit 60 includes a spinner table 62 that holds under suction the workpiece 200 on a holding surface 61 and rotates about an axis parallel with the Z-axis direction; and an unillustrated cleaning water supply nozzle that supplies cleaning water to the workpiece 200 held under suction on the spinner table 62 rotating about the axis.

The transporting unit 70 transports the workpiece 200 in the processing apparatus 1. The transporting unit 70 includes a loading and unloading unit 71, a first transporting unit 72, and a second transporting unit 73. The loading and unloading unit 71 includes a pair of temporary placement rails 74 on which the workpiece 200 is to be temporarily placed; and an extracting and inserting unit 75 that unloads the workpiece 200 that has not yet undergone cutting processing from the cassette 51, temporarily places the workpiece 200 on the pair of temporary placement rails 74, and loads the workpiece 200 that has undergone the cutting processing and that is temporarily placed on the pair of temporary placement rails 74 into the cassette 51. The extracting and inserting unit 75 clamps an edge portion of the annular frame 205 mounted with the workpiece 200, and extracts and inserts the workpiece 200 from and into the cassette 51.

The first transporting unit 72 holds under suction the workpiece 200 temporarily placed on the pair of temporary placement rails 74, and transports the workpiece 200 to the holding table 10 in the loading and unloading region. In addition, the first transporting unit 72 transports the workpiece 200 that has been cleaned and that is placed on the spinner table 62 onto the pair of temporary placement rails 74. The first transporting unit 72 includes sucking and holding units 76 that are connected to an unillustrated vacuum suction source and are sucked from the vacuum suction source to thereby hold under suction the workpiece 200 temporarily placed on the pair of temporary placement rails 74 and the workpiece 200 on the spinner table 62.

The second transporting unit 73 transports the workpiece 200 that has undergone cutting processing and that is placed on the holding table 10 in the loading and unloading region to the spinner table 62 of the cleaning unit 60. The second transporting unit 73 includes sucking and holding units 77 that are connected to an unillustrated vacuum suction source and are sucked from the vacuum suction source to thereby hold under suction the workpiece 200 on the holding surface 11 of the holding table 10 in the loading and unloading region.

In addition, as illustrated in FIG. 2, the processing apparatus 1 includes a current value detecting sensor 80 that detects the current value of power supplied to the stator 242 of the spindle motor 24 (the current value will hereinafter be described as a load current value) and a damage detecting sensor 81. The current value detecting sensor 80 outputs the detected load current value to the control unit 100. Incidentally, the load current value is a value of a current flowing through the stator 242 of the spindle motor 24, and tends to rise when cutting resistance at a time of cutting the workpiece 200 is increased by a rise in processing load or the like due to dulling of the cutting edge 212 during cutting.

The damage detecting sensor 81 measures a state of damage to the point of the cutting edge 212 of the cutting blade 21, during cutting. The damage detecting sensor 81 is to measure, as a damaged state of the point, the occurrence of chipping or the like in which a part of the outer edge of the cutting edge 212 of the cutting blade 21 is lost.

As illustrated in FIG. 3, the damage detecting sensor 81 is provided to the blade cover 25. As illustrated in FIG. 2, the damage detecting sensor 81 includes a light emitting unit 811 and a light receiving unit 812 that are spaced from each other in the Y-axis direction of the blade cover 25 and between which an upper end of the cutting edge 212 of the cutting blade 21 is positioned.

The light emitting unit 811 emits pulsed light from an unillustrated light source to the light receiving unit 812. The light receiving unit 812 receives the pulsed light emitted from the light emitting unit 811, and outputs a detection result indicating a light amount of the received pulsed light to the control unit 100.

Incidentally, when chipping occurs at the point of the cutting edge 212 of the cutting blade 21 during cutting, the light amount of the light from the light emitting unit 811 which is received by the light receiving unit 812 is periodically increased from a light amount received before the occurrence of the chipping because the cutting blade 21 is rotating about the axis during the cutting. In addition, the light amount of the light from the light emitting unit 811 which is received by the light receiving unit 812 is gradually increased as the point of the cutting edge 212 of the cutting blade 21 during the cutting is worn.

Thus, the light receiving unit 812 of the damage detecting sensor 81 receives the light whose light amount changes depending on the occurrence of chipping and wear at the point of the cutting edge 212 of the cutting blade 21, and the damage detecting sensor 81 outputs a detection result indicating the light amount of the received light to the control unit 100. The damage detecting sensor 81 thereby measures the state of damage such as wear and chipping at the point of the cutting edge 212 of the cutting blade 21, during the cutting.

In addition, as illustrated in FIG. 3, the processing apparatus 1 includes a cutting water flow rate detecting sensor 82 and a cutting water temperature detecting sensor 83. The cutting water flow rate detecting sensor 82 detects a flow rate as an amount of supply of the cutting water supplied to the nozzles 261 and 262. The cutting water flow rate detecting sensor 82 outputs a result of the detection to the control unit 100. The cutting water temperature detecting sensor 83 detects the temperature of the cutting water supplied to the cutting edge 212 of the cutting blade 21 via the nozzles 261 and 262. The cutting water temperature detecting sensor 83 outputs a result of the detection to the control unit 100.

In addition, as illustrated in FIG. 1, the processing apparatus 1 includes a diameter detecting unit 84 that detects the diameter of the cutting edge 212 of the cutting blade 21. The diameter detecting unit 84 is provided at a position adjacent to the holding table 10 in such a manner as to be movable, together with the holding table 10, in the X-axis direction by the processing feed unit 41. The diameter detecting unit 84 is a unit for detecting the position in the Z-axis direction of the axis of the spindle 23 and the cutting blade 21 when the lower end of the point of the cutting edge 212 of the cutting blade 21 is positioned on the same plane as the holding surface 11. The diameter detecting unit 84 is also a unit for detecting the diameter of the cutting blade 21 by detecting the position in the Z-axis direction of the axis of the spindle 23 and the cutting blade 21 when the lower end of the point of the cutting edge 212 of the cutting blade 21 is positioned on the same plane as the holding surface 11. The cutting edge 212 is worn as cutting is performed. When the diameter of the cutting blade 21 is detected in any timing, a depth to which the cutting blade 21 cuts into the workpiece 200 can be controlled in consideration of an amount of wear of the cutting blade 21.

As illustrated in FIG. 4, the diameter detecting unit 84 includes a unit main body 843 including a pair of leg portions 841 that are spaced from each other in the Y-axis direction and between which the lower end of the cutting edge 212 of the cutting blade 21 can be inserted and a coupling portion 842 that couples lower ends of the pair of leg portions 841 to each other; a light emitting unit 844 provided to one leg portion 841 of the unit main body 843; and a light receiving unit 845 provided to the other leg portion 841.

The light emitting unit 844 emits pulsed light from an unillustrated light source to the other leg portion 841, that is, the light receiving unit 845. The light receiving unit 845 receives the pulsed light emitted from the light emitting unit 844, and outputs a detection result indicating a light amount of the received pulsed light to the control unit 100.

Incidentally, the light amount of the light from the light emitting unit 844 which is received by the light receiving unit 845 is gradually decreased as the lower end of the cutting edge 212 of the cutting blade 21 entering between the pair of leg portions 841 is lowered. Thus, the light receiving unit 845 of the diameter detecting unit 84 receives the light whose light amount is decreased by lowering of the point of the cutting edge 212 of the cutting blade 21, and the diameter detecting unit 84 outputs a detection result indicating the light amount of the received light to the control unit 100. The control unit 100 detects a timepoint at which the light amount indicated by the detection result of the light receiving unit 845 becomes a light amount at a time when the lower end of the point of the cutting edge 212 of the cutting blade 21 is positioned on the same plane as the holding surface 11, and detects, from a detection result of the Z-axis direction position detecting unit, the position in the Z-axis direction of the axis of the cutting blade 21 and the spindle 23 at a time when the lower end of the point of the cutting edge 212 of the cutting blade 21 is positioned on the same plane as the holding surface 11.

In addition, the processing apparatus 1 includes a detecting sensor 85 that detects whether or not the extracting and inserting unit 75 of the loading and unloading unit 71 of the transporting unit 70 is clamping the annular frame 205; a detecting sensor 86 that detects whether or not the first transporting unit 72 of the transporting unit 70 is holding under suction the workpiece 200; and a detecting sensor 87 that detects whether or not the second transporting unit 73 of the transporting unit 70 is holding under suction the workpiece 200. In addition, the processing apparatus 1 includes a detecting sensor 88 that detects whether or not the holding table 10 is holding under suction the workpiece 200; and a detecting sensor 89 that detects whether or not the spinner table 62 of the cleaning unit 60 is holding under suction the workpiece 200. The detecting sensors 85, 86, 87, 88, and 89 output a detection result to the control unit 100.

Incidentally, the detecting sensor 85 detecting that the extracting and inserting unit 75 is not clamping the annular frame 205, the detecting sensor 86 detecting that the first transporting unit 72 is not holding under suction the workpiece 200, and the detecting sensor 87 detecting that the second transporting unit 73 is not holding under suction the workpiece 200 indicate that the transporting unit 70 has failed to transport the workpiece 200, that is, that the transporting unit 70 has caused a transportation error, which is an abnormality in transportation of the workpiece 200 by the transporting unit 70.

Incidentally, the detecting sensors 86 and 87 detect whether or not the transporting units 72 and 73 are holding under suction the workpiece 200, according to a determination made by the control unit 100 as to whether or not detection results of the detecting sensors 86 and 87 are equal to or lower than a predetermined pressure determined in advance. When the control unit 100 determines that the detection results of the detecting sensors 86 and 87 are equal to or lower than the predetermined pressure determined in advance, the transporting units 72 and 73 are detected to be holding under suction the workpiece 200. When the control unit 100 determines that the detection results of the detecting sensors 86 and 87 exceed the predetermined pressure determined in advance, the transporting units 72 and 73 are detected not to be holding under suction the workpiece 200.

In addition, the detecting sensors 88 and 89 detecting that the holding table 10 and the spinner table 62 are not holding under suction the workpiece 200 indicates that the holding table 10 and the spinner table 62 have failed to hold the workpiece 200 in a normal state, that is, that the holding table 10 and the spinner table 62 have caused a holding error, which is an abnormality in holding the workpiece 200.

Incidentally, the detecting sensors 88 and 89 detect whether or not the holding table 10 and the spinner table 62 are holding under suction the workpiece 200, according to a determination made by the control unit 100 as to whether or not detection results of the detecting sensors 88 and 89 are equal to or lower than a predetermined pressure determined in advance. When the control unit 100 determines that the detection results of the detecting sensors 88 and 89 are equal to or lower than the predetermined pressure determined in advance, the holding table 10 and the spinner table 62 are detected to be holding under suction the workpiece 200. When the control unit 100 determines that the detection results of the detecting sensors 88 and 89 exceed the predetermined pressure determined in advance, the holding table 10 and the spinner table 62 are detected not to be holding under suction the workpiece 200.

The control unit 100 also makes the processing apparatus 1 perform processing operation on the workpiece 200, by controlling each of constituent elements of the processing apparatus 1. Incidentally, the control unit 100 is a computer including an arithmetic processing apparatus having a microprocessor such as a central processing unit (CPU), a storage apparatus having a memory such as a read only memory (ROM) or a random access memory (RAM), and an input-output interface apparatus. The arithmetic processing apparatus of the control unit 100 performs arithmetic processing according to a computer program stored in the storage apparatus, and outputs a control signal for controlling the processing apparatus 1 to each of the constituent elements of the processing apparatus 1 via the input-output interface apparatus.

The control unit 100 is connected with a display unit 110 including a liquid crystal display apparatus or the like that displays the state of the processing operation, an image, or the like, an input unit 120 used when an operator registers processing content information or the like, and a notifying unit 130 that makes a notification to the operator. The input unit 120 includes a touch panel provided to the display unit 110. The notifying unit 130 makes a notification to the operator by emitting at least one of sound and light.

In addition, the control unit 100 detects the state of chipping and wear at the point of the cutting edge 212 of the cutting blade 21 on the basis of a detection result from the light receiving unit 812 of the damage detecting sensor 81. Specifically, when a received light amount indicated by a measurement result from the light receiving unit 812 of the damage detecting sensor 81 is equal to or more than a predetermined value determined in advance, without periodically increasing or decreasing, the control unit 100 detects that the cutting edge 212 of the cutting blade 21 is at a wear limit at which the cutting edge 212 is too worn to be suitable for cutting the workpiece 200.

In addition, when the received light amount indicated by the measurement result output from the light receiving unit 812 of the damage detecting sensor 81 periodically increases or decreases, the control unit 100 detects that a part of the outer edge of the cutting edge 212 of the cutting blade 21 is lost and thus chipping (that is, damage) has occurred in the cutting edge 212. The control unit 100 calculates an amount of increase per unit time of the received light amount on the basis of the measurement result output from the light receiving unit 812 of the damage detecting sensor 81. The control unit 100 detects an amount of wear of the cutting edge 212 of the cutting blade 21 per unit time on the basis of the calculated amount of increase per unit time of the received light amount. When the detected amount of wear is equal to or more than a predetermined value determined in advance, the control unit 100 detects that the amount of wear per unit time of the cutting edge 212 of the cutting blade 21 is abnormal.

In addition, the control unit 100 detects the position in the Z-axis direction of the axis of the spindle 23 and the cutting blade 21 when the lower end of the point of the cutting edge 212 of the cutting blade 21 is positioned on the same plane as the holding surface 11, on the basis of the detection result from the light receiving unit 845 of the diameter detecting unit 84 and the detection result of the Z-axis direction position detecting unit. The control unit 100 thereby detects the diameter of the cutting blade 21. Specifically, the control unit 100 detects the detection result of the Z-axis direction position detecting unit when the light amount of the light indicated by the detection result output from the light receiving unit 845 becomes a light amount when the lower end of the point of the cutting edge 212 of the cutting blade 21 is positioned on the same plane as the holding surface 11, as the position in the Z-axis direction of the axis of the cutting blade 21 and the spindle 23 when the lower end of the point of the cutting edge 212 of the cutting blade 21 is positioned on the same plane as the holding surface 11. Because the reference position in the Z-axis direction is the position on the same plane as the holding surface 11, the control unit 100 detects, as the radius of the cutting blade 21, the detection result of the Z-axis direction position detecting unit when the light amount of the light indicated by the detection result output from the light receiving unit 845 becomes the light amount when the lower end of the point of the cutting edge 212 of the cutting blade 21 is positioned on the same plane as the holding surface 11. The control unit 100 then detects the diameter of the cutting blade 21.

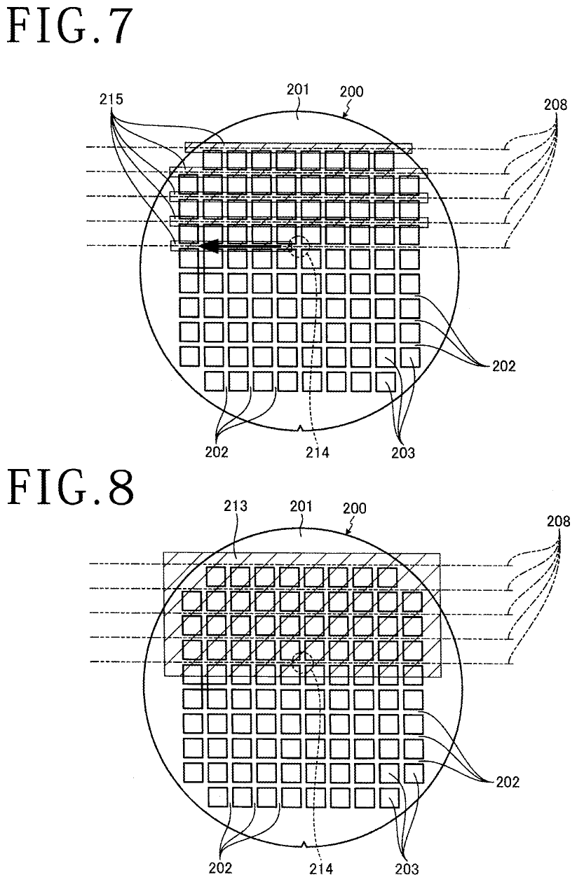

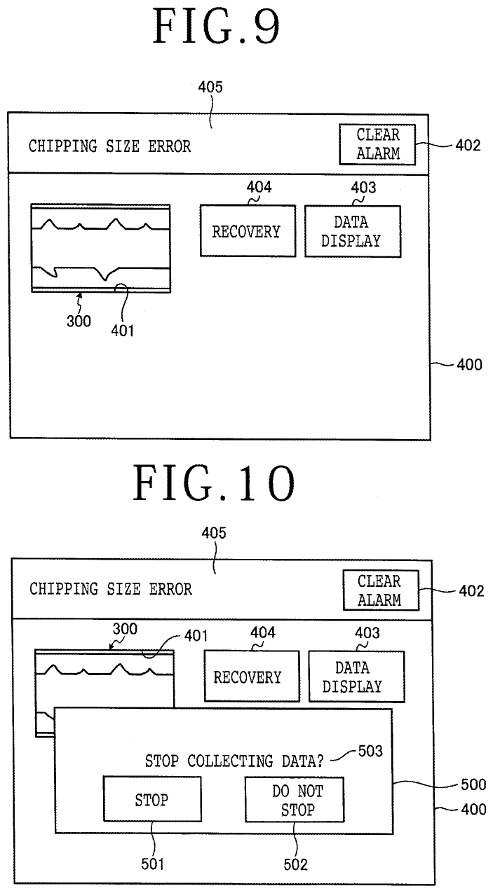

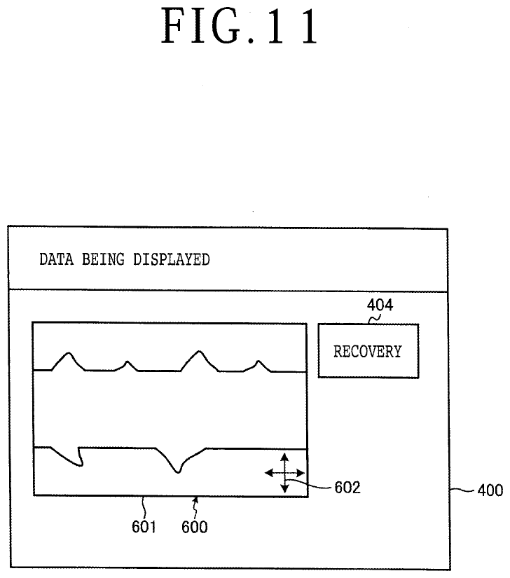

Description will next be made of the processing operation of the processing apparatus 1 which is performed by control of each constituent element of the processing apparatus 1 by the control unit 100. FIG. 5 is a plan view schematically depicting the workpiece that is under cutting processing by the processing apparatus illustrated in FIG. 1. FIG. 6 is a diagram depicting an example of an image obtained by imaging a part of the workpiece at a time of a kerf check performed during the cutting processing by the processing apparatus illustrated in FIG. 1. FIG. 7 is a plan view depicting an example of a wafer position at which image data as data collected by a data collecting section of the processing apparatus illustrated in FIG. 1 is obtained. FIG. 8 is a plan view depicting another example of the wafer position at which the image data as data collected by the data collecting section of the processing apparatus illustrated in FIG. 1 is obtained. FIG. 9 is a diagram depicting an example of a display screen displayed on the display unit when an abnormality detecting section of the control unit of the processing apparatus illustrated in FIG. 1 detects a chipping size error. FIG. 10 is a diagram depicting an example of the display screen that is displayed when a recovery region or a data display region of the display screen illustrated in FIG. 9 is operated during obtainment of the image data by the data collecting section. FIG. 11 is a diagram depicting an example of the display screen that is displayed when the data display region of the display screen illustrated in FIG. 9 is operated after the obtainment of the image data by the data collecting section.

The above-described control unit 100 performs the processing operation of cutting the workpiece 200 held under suction on the holding table 10 by the cutting blade 21, by controlling each constituent element of the processing apparatus 1. Before the processing operation, in the processing apparatus 1, the cassette 51 housing workpieces 200 is installed on the cassette elevator 50, and the dressing board 210 is installed on a holding surface 16 of the sub-chuck table 15. In addition, processing conditions are set in the storage apparatus of the control unit 100, and when the control unit 100 receives an instruction for starting the processing operation from the operator or the like, the control unit 100 starts the processing operation of the processing apparatus 1.

When starting the processing operation, the control unit 100 controls the transporting unit 70 to extract one workpiece 200 from the cassette 51, and mount the workpiece 200 on the holding surface 11 of the holding table 10 in the loading and unloading region via the adhesive tape 206. In the processing operation, the control unit 100 holds under suction the workpiece 200 on the holding surface 11 via the adhesive tape 206, clamps the annular frame 205 by the clamp units 12, rotates the spindle 23 about the axis, and supplies the cutting water from the nozzles 261 and 262. The control unit 100 moves the holding table 10 from the loading and unloading region toward the processing region to a position below the imaging unit 30 by controlling the moving unit 40, and images the workpiece 200 held under suction on the holding table 10 by the imaging unit 30. The imaging unit 30 obtains an image for, for example, carrying out alignment that aligns the workpiece 200 and the cutting blade 21 with each other, and the control unit 100 carries out the alignment on the basis of the image imaged by the imaging unit 30.

In the processing operation, the control unit 100 controls the moving unit 40 and the like on the basis of the processing conditions, to perform cutting processing by making the cutting blade 21 cut into a planned dividing line 202 of the workpiece 200 until it reaches the adhesive tape 206 while moving the cutting blade 21 and the workpiece 200 relative to each other along the planned dividing line 202. The control unit 100 cuts the planned dividing line 202 of the workpiece 200 according to the processing conditions, forms a processed groove 208 (indicated by a chain double-dashed line in FIG. 5) penetrating the workpiece 200 in the planned dividing line 202, and thereby divides the workpiece 200 into individual chips 207. After the control unit 100 performs the cutting processing on all of the planned dividing lines 202 of the workpiece 200, the control unit 100 moves the holding table 10 from the processing region to the loading and unloading region by controlling the moving unit 40.

The control unit 100 stops moving the holding table 10 in the loading and unloading region by controlling the moving unit 40 and the like, stops holding under suction the workpiece 200 on the holding table 10, cancels the clamping of the clamp units 12, and transports the workpiece 200 from the holding table 10 to the spinner table 62 of the cleaning unit 60 by controlling the transporting unit 70. The control unit 100 cleans the workpiece 200 by controlling the cleaning unit 60, and loads the workpiece 200 that has undergone the cutting processing into the cassette 51 after moving the workpiece 200 onto the temporary placement rails 74 by controlling the transporting unit 70. When the control unit 100 has divided all of the workpieces 200 in the cassette 51 into chips 207 by performing the cutting processing on the workpieces 200, the control unit 100 ends the processing operation.

Thus, by controlling each constituent element of the processing apparatus 1, the control unit 100 performs the cutting processing on each planned dividing line 202 of the workpiece 200 by the cutting blade 21, and thereby forms a processed groove 208 indicated by a chain double-dashed line in FIG. 5 in each planned dividing line 202. In addition, the control unit 100 performs a kerf check at a predetermined timing (for example, each time the cutting processing is performed on a predetermined number of planned dividing lines 202 or each time the cutting processing is performed on a predetermined number of workpieces 200) in the processing operation. When the control unit 100 performs a kerf check, the control unit 100 images, by the imaging unit 30, a processed groove 208 at a predetermined position (for example, a position 214 enclosed by a dotted line circle in FIG. 5) of the workpiece 200 which position is specified by a processing condition, and thereby obtains, for example, an image 300 an example of which is illustrated in FIG. 6.

In addition, as illustrated in FIG. 1, the control unit 100 includes an abnormality detecting section 101, a processing stopping section 102, a data collecting section 103, and a data analyzing section 104.

The abnormality detecting section 101 detects an abnormality that has occurred during the processing operation, by checking the quality of the processed groove 208, during the processing operation of the processing apparatus 1. The abnormality detecting section 101 extracts the planned dividing line 202, the processed groove 208, and chips 209 (hereinafter written as chippings) formed at both edges of the processed groove 208 from the image 300 obtained when the kerf check is performed. The control unit 100 detects a normal position 301 at which the processed groove 208 in the planned dividing line 202 is to be formed, the normal position being specified by a processing condition (the normal position is a central position in the width direction of the planned dividing line 202 in the embodiment), a central position 302 in the width direction of the processed groove 208, a width 303 of the processed groove 208, a size 304 of a largest chipping 209 (distance between a tip of a chipping 209 which is most distant from the processed groove 208 among a plurality of chippings 209 and one of edges of the processed groove 208), and a distance 305 between the normal position 301 at which the processed groove 208 is to be formed and the central position 302 in the width direction of the processed groove 208 (the distance will hereinafter be written as a cut position offset).

Thus, in the embodiment, the kerf check refers to checking whether or not the cut position offset 305, the width 303 of the processed groove 208, and the size 304 of the chipping 209 are within an allowable range. The abnormality detecting section 101 checks the quality of the processed groove 208 by determining whether or not the cut position offset 305, the detected width 303 of the processed groove 208, and the size 304 of the chipping 209 are each within an allowable range specified by a processing condition.

The processing stopping section 102 stops the cutting processing by the cutting unit 20 when an abnormality is detected by the abnormality detecting section 101. The processing stopping section 102 continues the processing operation when the abnormality detecting section 101 determines that all of the cut position offset 305, the width 303 of the processed groove 208, and the size 304 of the chipping 209 are within the allowable ranges. When the abnormality detecting section 101 determines that at least one of the cut position offset 305, the width 303 of the processed groove 208, and the size 304 of the chipping 209 is not within the allowable range (that is, when a kerf check error as an abnormality is detected by the abnormality detecting section 101), the processing stopping section 102 stops the processing operation (that is, the cutting processing by the cutting unit 20), and makes a notification to the operator by operating the notifying unit 130.

Incidentally, not being within the allowable range at the time of the kerf check will hereinafter be written as a kerf check error, which is an abnormality of the processed groove 208, and the size 304 of the chipping 209 not being within the allowable range will hereinafter be written as a chipping size error. In addition, when the control unit 100 performs the kerf check, the control unit 100 stores the detected cut position offset 305, the detected width 303 of the processed groove 208, and the detected size 304 of the chipping 209. Thus, the abnormality detecting section 101 detects a kerf check error from the image 300 of the processed groove 208 imaged by the imaging unit 30.

In addition, the abnormality detecting section 101 detects that the cutting edge 212 of the cutting blade 21 is at a wear limit, that chipping has occurred in the cutting edge 212 of the cutting blade 21, and that the amount of wear per unit time of the cutting edge 212 of the cutting blade 21 is an abnormality, that is, detects a blade error as an abnormality, on the basis of a detection result of the damage detecting sensor 81, during the processing operation of the processing apparatus 1.

When the abnormality detecting section 101 detects that the cutting edge 212 of the cutting blade 21 is at a wear limit, that chipping has occurred in the cutting edge 212 of the cutting blade 21, or that the amount of wear unit time per of the cutting edge 212 of the cutting blade 21 is an abnormality (that is, the abnormality detecting section 101 detects a blade error), on the basis of the detection result of the damage detecting sensor 81, during the processing operation of the processing apparatus 1, the processing stopping section 102 stops the processing operation, and makes a notification to the operator by operating the notifying unit 130.

In addition, the abnormality detecting section 101 detects at least that the extracting and inserting unit 75 is not clamping the annular frame 205, that the first transporting unit 72 is not holding under suction the workpiece 200, or that the second transporting unit 73 is not holding under suction the workpiece 200, that is, detects a transportation error as an abnormality, on the basis of detection results of the detecting sensors 85, 86, and 87, during the processing operation of the processing apparatus 1.

When the abnormality detecting section 101 detects that the extracting and inserting unit 75 is not clamping the annular frame 205, that the first transporting unit 72 is not holding under suction the workpiece 200, or that the second transporting unit 73 is not holding under suction the workpiece 200 (that is, the abnormality detecting section 101 detects a transportation error), on the basis of the detection results of the detecting sensors 85, 86, and 87, during the processing operation of the processing apparatus 1, the processing stopping section 102 stops the processing operation, and makes a notification to the operator by operating the notifying unit 130.

In addition, the abnormality detecting section 101 detects holding errors as abnormalities of the holding table 10 and the spinner table 62 on the basis of detection results of the detecting sensors 88 and 89, during the processing operation of the processing apparatus 1.

When the abnormality detecting section 101 detects a holding error of one of the holding table 10 and the spinner table 62 (that is, the abnormality detecting section 101 detects a holding error), during the processing operation of the processing apparatus 1, the processing stopping section 102 stops the processing operation, and makes a notification to the operator by operating the notifying unit 130.

In addition, the abnormality detecting section 101 determines whether or not a flow rate as a detection result of the cutting water flow rate detecting sensor 82 is within an allowable range. The abnormality detecting section 101 determines whether or not a temperature as a detection result of the cutting water temperature detecting sensor 83 is within an allowable range.

When the abnormality detecting section 101 determines that the flow rate as the detection result of the cutting water flow rate detecting sensor 82 is within the allowable range, during the processing operation of the processing apparatus 1, the processing stopping section 102 continues the processing operation. When the abnormality detecting section 101 determines that the flow rate as the detection result of the cutting water flow rate detecting sensor 82 is not within the allowable range (that is, the abnormality detecting section 101 detects a cutting water flow rate error as an abnormality), the processing stopping section 102 stops the processing operation, and makes a notification to the operator by operating the notifying unit 130.

When the abnormality detecting section 101 determines that the temperature as the detection result of the cutting water temperature detecting sensor 83 is within the allowable range, during the processing operation of the processing apparatus 1, the processing stopping section 102 continues the processing operation. When the abnormality detecting section 101 determines that the temperature as the detection result of the cutting water temperature detecting sensor 83 is not within the allowable range (that is, the abnormality detecting section 101 detects a cutting water temperature error as an abnormality), the processing stopping section 102 stops the processing operation, and makes a notification to the operator by operating the notifying unit 130.

The data collecting section 103 obtains data related to the processing apparatus 1 during a standby time period between the stopping of the processing operation by the processing stopping section 102 and completion of an operation of recovery from the kerf check error, the blade error, the transportation error, the holding error, the cutting water flow rate error, or the cutting water temperature error (operation for resuming the processing operation) which is performed by the operator.

In the embodiment, when the abnormality detecting section 101 detects one of the kerf check error, the blade error, the transportation error, and the holding error and the processing stopping section 102 stops the processing operation, the data collecting section 103 drives the moving unit 40 and the imaging unit 30 or the like to image processed grooves 208 on an upstream side (corresponding to a plurality of regions) in order from a position cut immediately before the stopping of the processing operation on the workpiece 200, and thereby collect and obtain, as image data, images of the processed grooves 208 on the upstream side in order from the position cut immediately before the processing is stopped. Incidentally, FIG. 7 illustrates, by parallel oblique lines, positions 215 at which the imaging unit 30 performs imaging and obtains the image data on the top surface 201 of the workpiece 200.

In addition, in the present invention, when the abnormality detecting section 101 detects one of the kerf check error, the blade error, the transportation error, and the holding error, and the processing stopping section 102 stops the processing operation, the data collecting section 103 may drive the moving unit 40 and the imaging unit 30 or the like to image the whole of a region 213 (indicated by parallel oblique lines in FIG. 8) in which the processed grooves 208 are formed on the top surface 201 of the workpiece 200 including the position cut immediately before the stopping of the processing operation on the workpiece 200, and thereby collect and obtain the image data. Incidentally, FIG. 8 illustrates, by parallel oblique lines, the region 213 in which the imaging unit 30 performs imaging and obtains the image data on the top surface 201 of the workpiece 200. Incidentally, in a case where the image data of the region 213 illustrated in FIG. 8 is obtained, the position of the workpiece 200 at which an error has occurred during the cutting processing for the processed grooves 208 can easily be identified when the cause of the error is investigated afterward.

Thus, before the operator performs an operation of recovery from an error, the data collecting section 103 moves the holding table 10 and the imaging unit 30 relative to each other in a direction horizontal to the holding surface 11, and obtains the image data of the processed grooves 208. Because the data collecting section 103 collects the image data, not only is it possible to determine the operation of recovery from the error but it is also possible to determine the cause of a chipping error or the like by reexamining the image data afterward.

In addition, when the abnormality detecting section 101 detects one of the kerf check error, the blade error, the transportation error, and the holding error and the processing stopping section 102 stops the processing operation, the data collecting section 103 controls the moving unit 40 and the diameter detecting unit 84 to detect the diameter of the cutting blade 21 by the diameter detecting unit 84. The data collecting section 103 stores, in the storage apparatus, the obtained image data, the detected diameter of the cutting blade 21, and one of the kerf check error, the blade error, the transportation error, and the holding error detected by the abnormality detecting section 101 or the like in association with each other. Thus, the kind of the data collected by the data collecting section 103 is preferably associated with the kind of the error.

The data analyzing section 104 analyzes the image data obtained and collected by the data collecting section 103. In the embodiment, the data analyzing section 104 detects a processed groove 208 from the image data obtained and collected by the data collecting section 103, and detects the cut position offset 305, the width 303 of the processed groove 208, and the size 304 of the chipping 209 at each predetermined interval in the longitudinal direction of the processed groove 208.

The data analyzing section 104 stores the detected cut position offset 305, the detected width 303 of the processed groove 208, and the detected size 304 of the chipping 209 and a position on the top surface 201 of the workpiece 200 in association with each other. The data analyzing section 104 calculates an average value and a maximum value of each of the cut position offset 305, the width 303 of the processed groove 208, and the size 304 of the chipping 209 that are already stored, and analyzes tendencies of changes therein.

In the embodiment, when the abnormality detecting section 101 detects the kerf check error and the processing stopping section 102 stops the processing operation, the operator or the like, for example, performs correction of a cutting processing position of the cutting blade 21, dressing that makes the cutting blade 21 cut into the dressing board 210, or replacement of the cutting blade 21 as the operation of recovery from the kerf check error. Specifically, in a case where the kerf check error indicates that the width 303 of the processed groove 208 is not within the allowable range or indicates a chipping size error, the operator replaces the cutting blade 21, or makes the processing apparatus 1 perform dressing, by operating the input unit 120, for example.

In a case where the kerf check error indicates that the cut position offset 305 is not within the allowable range, the operator operates the input unit 120 to set the imaging unit 30 to a planned processing position, register an offset between a hairline displayed at the center of an imaging screen and an actually processed groove 208, and have the processing apparatus 1 perform hairline alignment that updates positional relation between the imaging unit 30 and the cutting blade 21 or move and register the cutting processing position of the cutting blade 21 to make correction. In addition, in a case where the kerf check error indicates that the processed groove 208 is not found, the operator, for example, operates the input unit 120 to make the processing apparatus 1 detect the diameter of the cutting blade 21 by the diameter detecting unit 84, and set up the position in the Z-axis direction of the cutting unit 20 during the cutting processing to a position at which the workpiece 200 can be cut (that is, perform a blade setup) again.

In a case where the kerf check error indicates a chipping size error, for example, the control unit 100 displays a display screen 400 illustrated in FIG. 9 on the display unit 110. Set on the display screen 400 illustrated in FIG. 9 are an image display region 401 that displays the image 300 obtained when the kerf check is performed; an alarm clearing region 402 for inputting an instruction for stopping the notification of the notifying unit 130 to the control unit 100; a data display region 403 for inputting an instruction for displaying the image data collected by the data collecting section 103 or the like to the control unit 100; a recovery region 404 for inputting an instruction for displaying a menu for recovery from an abnormality such as the kerf check error to the control unit 100; and an error content display region 405 that indicates the kind of the error. When the operator operates the alarm clearing region 402 on the display screen 400, the control unit 100 stops the notification of the notifying unit 130.

In addition, when the operator operates the data display region 403 or the recovery region 404 on the display screen 400 while the data collecting section 103 collects the image data or the like, the control unit 100 displays a confirmation screen 500 for confirming whether or not to stop the collection of the image data or the like by the data collecting section 103 on the display screen 400 in such a manner that the confirmation screen 500 is superimposed on the display screen 400.

Incidentally, set on the confirmation screen 500 are a stop region 501 for inputting an instruction for stopping the collection of the image data or the like by the data collecting section 103 to the control unit 100; a continuation region 502 for inputting an instruction for continuing the collection of the image data or the like by the data collecting section 103 to the control unit 100; and a region 503 that displays a message for confirming whether or not to stop the collection of the image data or the like by the data collecting section 103.

In addition, when the operator operates the data display region 403 on the display screen 400 after the data collecting section 103 has collected the image data or the like, the control unit 100 displays an image data display screen 600 displaying the image data collected and obtained by the data collecting section 103 on the display screen 400 in such a manner that the image data display screen 600 is superimposed on the display screen 400. Incidentally, set on the image data display screen 600 are an image data display region 601 that displays the image data; and a cursor 602 for inputting an instruction for changing the position of the image data displayed in the image data display region 601 to the control unit 100. The pieces of image data of all of the planned dividing lines 202 can be displayed in order on the image data display screen 600 by operating the cursor 602, so that a degree to which the processed grooves 208 as a whole are offset can be identified. In addition, in a case where the processed grooves 208 are not found, the pieces of image data of all of the planned dividing lines 202 can be displayed in order on the image data display screen 600 by operating the cursor 602, so that whether or not the processed grooves 208 are really absent can be identified. In addition, instead of operating the cursor 602, the image data being displayed may be changed by scrolling the image data display screen 600 vertically and horizontally.

In addition, when the operator operates the recovery region 404 on the display screen 400 after the data collecting section 103 has collected the image data or the like, the control unit 100 displays an unillustrated menu on the display screen 400. Set in the menu are a region for giving an instruction for resuming the processing operation; a region for giving an instruction for dressing of the cutting blade 21; a region for giving an instruction for correcting a cut position; a region for giving an instruction for hairline alignment; a region for making replacement of the cutting blade 21; and the like. In order to determine the recovery operation to be performed in these regions of the menu, the operator displays the image data display screen 600 in such a manner that the image data display screen 600 is superimposed on the display screen 400, by operating the data display region 403, and checks, for example, whether the chippings 209 have occurred suddenly (checks whether skipping of chips 207 has occurred and the cutting blade 21 is damaged, and resumes the processing when there is no problem) or whether the chippings 209 have a tendency of gradually becoming larger (performs dressing because conditions of the cutting blade 21 are estimated to be degraded).

Functions of the abnormality detecting section 101, the processing stopping section 102, the data collecting section 103, and the data analyzing section 104 of the control unit 100 described above are implemented by the arithmetic processing apparatus of the control unit 100 by executing a computer program stored in the storage apparatus.

In the processing apparatus 1 according to the embodiment described above, when the abnormality detecting section 101 detects one of the kerf check error, the blade error, the transportation error, the holding error, the cutting water flow rate error, and the cutting water temperature error, the processing stopping section 102 stops the processing operation, and the data collecting section 103 detects the image data and the diameter of the cutting blade 21 as data of the processing apparatus 1. Thus, the processing apparatus 1 collects the image data useful for analyzing the cause of each error and the diameter of the cutting blade 21 as data for checking the state of the cutting unit 20 while the processing operation is stopped (time period between giving a notification by an operation of the notifying unit 130 and starting a recovering operation after the notifying unit 130 is stopped by, for example, operating the alarm clearing region 402 of the display unit 110). Thus, a processing stop time period can be utilized effectively.

As a result, the processing apparatus 1 according to the embodiment has an effect of being able to effectively utilize a time period during which the processing apparatus 1 is stopped.

In addition, in the processing apparatus 1 according to the embodiment, the data collecting section 103 collects the image data obtained by imaging the processed top surface 201 of the workpiece 200. The obtained image data can thus be utilized by the operator for analyzing the cause of an error. Further, in the processing apparatus 1 according to the embodiment, the data analyzing section 104 can analyze, for example, a tendency of change such as whether the size 304 of the chipping 209, the width 303 of the processed groove 208, or the like has a tendency to increase or decrease or whether the chipping 209 has occurred suddenly, during a time period during which the processing apparatus 1 is stopped, and provide the tendency of change to the operator. An effect is thus produced in that the operator can identify the cause of the error, and perform an appropriate recovery operation.

In addition, in the processing apparatus 1 according to the embodiment, the data collecting section 103 detects the diameter of the cutting blade 21. Thus, data that can be used for future improvement in quality of the cutting processing is obtained.

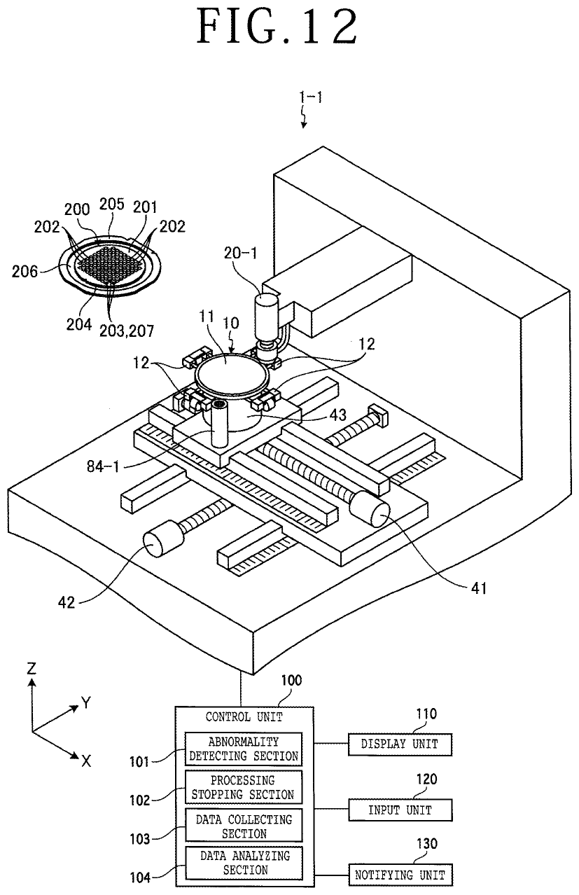

It is to be noted that the present invention is not limited to the foregoing embodiment and modifications. That is, the present invention can be modified and carried out in various manners without departing from the gist of the present invention. For example, the processing apparatus 1 according to the present invention is not limited to a cutting apparatus, and may be a laser processing apparatus illustrated in FIG. 12 or a grinding apparatus that grinds the workpiece 200. Incidentally, FIG. 12 is a perspective view depicting an example of a configuration of a processing apparatus according to a modification of the embodiment. In FIG. 12, the same parts as in the embodiment are denoted by the same reference numerals, and description thereof will be omitted.

A processing apparatus 1-1 illustrated in FIG. 12 is a laser processing apparatus that performs ablation processing on the workpiece 200 by irradiating the workpiece 200 with a laser beam of a wavelength absorbable by the workpiece 200, and thus forms processed grooves 208 along the planned dividing lines 202 of the workpiece 200. The processing apparatus 1-1 illustrated in FIG. 12 includes a laser beam irradiating unit 20-1 as a processing unit that irradiates the workpiece 200 with the laser beam, in place of the cutting unit 20, and includes a power meter 84-1 that is irradiated with the laser beam at a predetermined timing and measures the power of the laser beam applied by the laser beam irradiating unit 20-1, in place of the diameter detecting unit 84.

In addition, the processing apparatus 1 according to the present invention may detect the diameter of the cutting blade 21 on the basis of the light amount of light from the light emitting unit 811 which is received by the light receiving unit 812 of the damage detecting sensor 81, that is, may use the damage detecting sensor 81 as a diameter detecting unit.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A processing apparatus comprising:
a holding table having a holding surface configured to hold a workpiece;
a processing unit configured to process the workpiece held on the holding table;
a processing feed unit configured to move the holding table relative to the processing unit;
an imaging unit configured to image the workpiece held on the holding table; and
a control unit,
the control unit including
an abnormality detecting section configured to detect an abnormality in the processing apparatus,
a processing stopping section configured to stop processing by the processing unit when an abnormality is detected, and
a data collecting section configured to collect data related to the processing apparatus, during a standby time period between stopping of the processing and performing of an operation of recovery from the abnormality by an operator.

2. The processing apparatus according to claim 1, wherein
the control unit further includes a data analyzing section configured to analyze the data collected by the data collecting section.

3. The processing apparatus according to claim 1, wherein
the abnormality detecting section checks quality of a processed groove from an image of the processed groove imaged by the imaging unit.

4. The processing apparatus according to claim 1, further comprising:
a plurality of transporting units configured to transport the workpiece in the processing apparatus,
wherein the abnormality detecting section detects an abnormality in transportation by the transporting units.

5. The processing apparatus according to claim 1, wherein
the data collecting section images processed grooves in a plurality of regions by driving the imaging unit, and collects images of a plurality of the processed grooves, as the data.

6. The processing apparatus according to claim 1, wherein
the processing unit includes a cutting blade fixed to a distal end of a spindle and configured to form a processed groove in the workpiece and a motor configured to rotate the spindle,
the processing apparatus further includes a diameter detecting unit configured to detect a diameter of the cutting blade, and
the data collecting section detects the diameter of the cutting blade by the diameter detecting unit.
